(19) United States
(12) Patent Application Publication
(10) Pub. No.: US 2008/0266145 A1
(43) Pub. Date: Oct. 30, 2008

(54) MULTI-LINGUAL TEXT ENTRY USING A DYNAMICALLY RECONFIGURABLE KEYBOARD

(76) Inventors: Dinesh Verma, Mount Kisco, NY (US); Paridhi S. Verma, Mount Kisco, NY (US)

Correspondence Address: HOFFMAN WARNICK LLC, 75 State Street, 14th Floor, ALBANY, NY, 12207, US

(21) Appl. No.: 12/172,420

(22) Filed: Jul. 14, 2008

Related U.S. Application Data
(63) Continuation of application No. 11/458,523, filed on Jul. 19, 2006.

(51) Int. Cl. H03M 11/00

(52) U.S. Cl. 341/23

(57) ABSTRACT

The invention is directed to user-friendly multi-lingual text entry using a dynamically reconfigurable keyboard. A method for dynamically reconfiguring a keyboard according to an embodiment of the invention includes: displaying a first set of characters on the keyboard; providing language settings to an upper level system manager of a keyboard driver; communicating reconfiguration information corresponding to the language settings from the upper level system manager of the keyboard driver to a lower level device driver of the keyboard driver; and dynamically reconfiguring the keyboard to display a second set of characters.

### CROSS-REFERENCE TO RELATED APPLICATIONS

This application is a Continuation application of co-pending patent application Ser. No. 11/458,523, filed Jul. 19, 2006, entitled “Multi-Lingual Text Entry Using a Dynamically Reconfigurable Keyboard,” which is hereby incorporated by reference.

### BACKGROUND OF THE INVENTION

1. Field of the Invention

The present invention generally relates to keyboards. More specifically, the present invention is directed to user-friendly multi-lingual text entry using a dynamically reconfigurable keyboard.

2. Related Art

With increasing globalization and multi-national use of computers, many people are using computers to support multiple languages at the same time. Common tasks requiring multi-lingual input include: creating documents in mixed language text; composing an email to be sent to a person in a first language and composing an email to be sent to another person in a second language; and switching from a website which provides form-based input in one language to another website which uses another language. Unfortunately, current methods that enable the input of multi-lingual text are clumsy and difficult to use.

Support of multi-lingual text is currently offered in the form of onscreen keyboards, keyboard remappers, mixed-language keyboards, and statically reconfigurable keyboards. Each of these current solutions is deficient.

Onscreen Keyboards.

Many software packages provide the capability to switch the keyboard layout to that of a different language. Such a software package typically allows a user to select a language mode, and then displays the keyboard layout for that language on the screen. The user can select the characters from the keyboard (e.g., using a mouse or a pen for handheld devices), which appear in the currently active application.

Onscreen keyboards provide a flexible manner of entering input in different languages, but suffer from a clumsy interface. The user has to move the mouse over the onscreen keyboard to select characters. This is repetitive and difficult to maintain for long texts. Another difficulty comes with the masking of the current application window. Since the onscreen keyboard occupies a portion of the display, the active application (e.g., a browser page or an open text editor) must be resized to avoid any overlap with the onscreen keyboard. Otherwise, the onscreen keyboard and the active application overlap each other when active, resulting in substantial annoyance to the user.

Keyboard Remappers.

Software packages exist which allow the remapping of existing keyboard layouts to map that of different languages. The remapping of keyboards allows a user to type on a keyboard as if it were of a different language (the current language selected by the user) instead of the language that the keyboard was originally designed for. This does not require a visual display. However, since the keyboards are typically marked with only one language, the user has to either remember the remapped layout (which is difficult without any visible characters), or use the keyboard remapper in conjunction with an onscreen keyboard, which has the annoying problem of interfering with the display window of the application.

Mixed Language Keyboards.

A mixed language keyboard presents characters on a keyboard in multiple languages. However, a mixed language keyboard is restricted for use only with the languages that it comes pre-marked with. Due to restrictions on the physical size of the keys, and the size of characters that can be placed on the physical keyboard, such multi-language keyboards can only offer support for a small number of languages, usually supporting two languages, but occasionally up to three languages.

Statically Reconfigurable Keyboards.

Statically Reconfigurable keyboards provide an easier mechanism for reconfiguring the arrangement of a keyboard than statically defined keyboards. However, a static reconfigurable keyboard can only be reconfigured in a static manner, at the installation of a system, and not during dynamic use of the system.

In order to support multi-lingual text input by users, the reconfiguration of the keyboard needs to occur dynamically during the use of the system by the user. However, such dynamic reconfiguration is made difficult due to the current structuring of the operating systems used in computers. Accordingly, there is a need for a mechanism that will allow dynamic reconfiguration of a keyboard based on a user's actions when using a computer.

### SUMMARY OF THE INVENTION

The present invention is directed to user-friendly multi-lingual text entry using a dynamically reconfigurable keyboard.

A first aspect of the present invention is directed to a method for dynamically reconfiguring a keyboard, comprising: displaying a first set of characters on the keyboard; providing language settings to an upper level system manager of a keyboard driver; communicating reconfiguration information corresponding to the language settings from the upper level system manager of the keyboard driver to a lower level device driver of the keyboard driver; and dynamically reconfiguring the keyboard to display a second set of characters.

A second aspect of the present invention is directed to a dynamically reconfigurable keyboard system, comprising: a keyboard including a plurality of keys, wherein each key includes a display for displaying a character; and a keyboard driver including an upper level system manager and a lower level device driver, wherein the upper level system manager is configured to communicate reconfiguration information corresponding to current language settings to the lower level device driver, and wherein the lower level device driver is configured to dynamically reconfigure the keyboard to display a second set of characters.

The illustrative aspects of the present invention are designed to solve the problems herein described and other problems not discussed.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts a dynamically reconfigurable keyboard in accordance with the present invention.

FIG. 2 depicts illustrative key reconfigurations in accordance with an embodiment of the invention.

The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

The present invention is directed to user-friendly multi-lingual text entry using a dynamically reconfigurable keyboard.

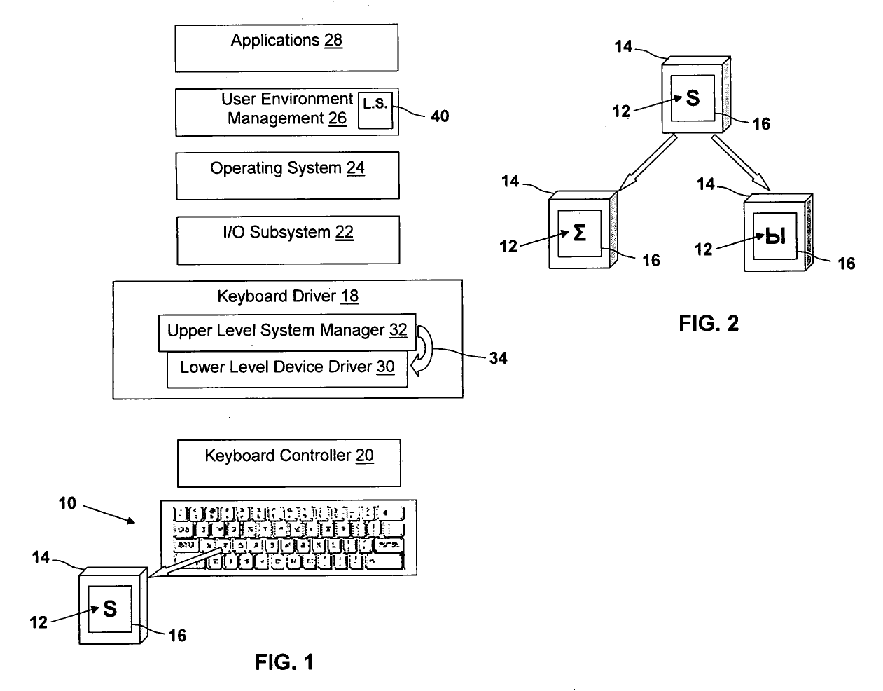

As shown in FIG. 1, the keyboard 10 of the present invention includes characters 12 on the keys 14 that can be reconfigured dynamically under the control of a computer or other suitable processing system. The reconfiguration of the keyboard 10 is linked with the current language settings selected by a user. The characters 12 on the keys 14 of the keyboard 10 are each provided using a respective display 16. The display 16 can comprise a liquid crystal display (LCD) positioned on or forming a part of a key 14 or can be provided using any other suitable display technology (e.g., light emitting diodes (LEDs)). The user can see the current characters 12 on the keys 14 of the keyboard 10 and use them effectively when typing. The layout of the keyboard 10 can be reconfigured dynamically, and there is no interference with the screen display area of other applications.

The keyboard driver 18 for the reconfigurable keyboard 10 is responsible for displaying the correct set of characters on the displays 16 of the keys 14. The keyboard driver 18 interfaces with the current language settings 40 of the operating system (selected and changeable by the user), and uses the information to drive the display characteristics of the keyboard 10 via the keyboard controller 20.

Computer operating systems typically are designed in a layered manner. The layers that deal with the processing of keyboard input typically follow the structure shown in the FIG. 1. The keyboard driver 18 reads the input from the keyboard 10. The keyboard driver 18 talks to the I/O subsystem 22 using a fixed set of interfaces that allow the I/O subsystem 22 to deal with the keyboard driver 18, as well as with other types of I/O devices. The I/O subsystem 22 interacts with the operating system 24, which interacts with other higher level applications. User environment management applications 26 are located above the operating system 24. Applications 28 are written on top of the operating system 24, and can leverage the support provided by the user environment management applications 26.

One challenge of implementing support for different language modes is the ability to interface between the keyboard driver 18 and the user environment management applications 26 (which are typically implemented in a generic manner in order to support many different types of keyboards). Another challenge in implementing support for different language modes is the ability to send updates from the I/O subsystem 22 to the keyboard driver 18 (in the prior art, keyboard drivers provided characters input by a user via a keyboard to an I/O subsystem, but did not receive commands from the I/O subsystem dictating output from the keyboard driver to the keyboard). As a result, simply implementing a new device driver for a reconfigurable keyboard is not sufficient to reconfigure the keyboard dynamically. Changing the operating system so that keyboard drivers can receive commands from the I/O subsystem as output is one option, but that would cause existing keyboard drivers to fail to operate. The present invention addresses these challenges by providing the keyboard driver 18 in the form of a split-level device driver that includes two portions: a lower level device driver 30 and an upper level system manager 32.

In accordance with the present invention, the lower level device driver 30 is configured to interact with the keyboard 10, while the upper level system manager 32 is configured to interact with the I/O subsystem 22. To this extent, the lower level device driver 30 acts similar to a traditional keyboard driver, while the upper level system manager 32 operates as a keyboard remapper level. However, instead of performing a keyboard remapping operation, the upper level system manager 32 communicates reconfiguration information 34 to the lower level device driver 30 requesting that the lower level device driver 30 reconfigure the characters 12 of the keyboard 10. In response, the lower level device driver 30 instructs the keyboard controller 20 to change the set of characters 12 output by the displays 16 on the keys 14 of the keyboard 10 in accordance with the reconfiguration information 34. The reconfiguration information 34 is based on the current language settings 40 of the operating system 24, which can be dynamically changed by a user. In response to such a change, and the resultant reconfiguration information 34 provided to the lower level device driver 30 by the upper level system manager 32, the lower level device driver 30 dynamically reconfigures the keyboard 10. For example, as shown in FIG. 2, the character 12 “S” has been dynamically reconfigured on the display 16 of a key 14 to “Σ” (Greek) and “bl” (Cyrillic).

The present invention can be implemented on any now known or later developed computer system that is capable of executing computer program code. The computer program code can be provided on a computer-readable medium or provided in any other suitable manner.

The foregoing description of the embodiments of this invention has been presented for purposes of illustration and description. It is not intended to be exhaustive or to limit the invention to the precise form disclosed, and many modifications and variations are possible.

What is claimed is:

1. A method for dynamically reconfiguring a keyboard, comprising:
displaying a first set of characters on the keyboard;
providing language settings to an upper level system manager of a keyboard driver;
communicating reconfiguration information corresponding to the language settings from the upper level system manager of the keyboard driver to a lower level device driver of the keyboard driver; and
dynamically reconfiguring the keyboard to display a second set of characters.

2. The method of claim 1, wherein the keyboard includes a plurality of keys, and wherein each key includes a display for displaying a character.

3. The method of claim 1, wherein the keyboard includes at least one key, wherein each key includes a display for displaying a character, based on the reconfiguration information, and wherein the lower level device driver of the keyboard driver is configured to:
dynamically reconfigure the character displayed on the display of at least one key of the keyboard.

4. A dynamically reconfigurable keyboard system, comprising:
a keyboard including a plurality of keys, wherein each key includes a display for displaying a character; and
a keyboard driver including an upper level system manager and a lower level device driver, wherein the upper level system manager is configured to communicate reconfiguration information corresponding to current language settings to the lower level device driver, and wherein the lower level device driver is configured to dynamically reconfigure the keyboard to display a second set of characters.
